(19) United States
(12) Patent Application Publication
(10) Pub. No.: US 2020/0144467 A1
(43) Pub. Date: May 7, 2020

(54) LIGHT-EMITTING DEVICE AND MANUFACTURING METHOD THEREOF

(71) Applicant: EPISTAR CORPORATION, Hsinchu (TW)

(72) Inventors: Pei-Hsuan LAN, Hsinchu (TW); Ching-Tai CHENG, Hsinchu (TW)

(21) Appl. No.: 16/182,707

(22) Filed: Nov. 7, 2018

(51) Int. Cl. H01L 33/60; H01L 33/50; H01L 33/62; H01L 33/48

(52) U.S. Cl. CPC H01L 33/60; H01L 33/50; H01L 33/62; H01L 2933/0033; H01L 2933/0041; H01L 2933/0058; H01L 33/486

(57) ABSTRACT

A light-emitting device includes a light-emitting element, an electrode, a reflective layer and a transparent layer. The reflective layer surrounds the light-emitting element and has an inner surface including a first portion and a second portion. There is a first angle included between the first portion and the first lateral surface, there is a second angle included between the second portion and the first lateral surface, and the first angle is larger than the second angle. The transparent layer includes an outer portion and an inner portion. The outer portion is formed above the upper surface and the inner portion is formed between the reflective layer and the first lateral surface. The outer portion includes wavelength conversion material and the inner portion does not comprise the wavelength conversion material.

### TECHNICAL FIELD

The disclosure relates in general to a light-emitting device and a manufacturing method thereof, and more particularly to a light-emitting device having a reflective layer and a manufacturing method thereof.

### BACKGROUND

For the solid-state light emitting elements, light-emitting diodes (LEDs) have the characteristics of low power consumption, low heat generation, long operational life, shockproof, small volume, quick response. Therefore, light-emitting diodes have been adopted widely in demands for light emitting elements within various fields, for instance, vehicles, home appliances, and lighting lamps.

Conventional light-emitting device includes a light-emitting element and a reflective layer surrounding the entire lateral surface of the light-emitting element. However, if the reflective layer is fully contacting the lateral surface, such that the light extraction of the light-emitting element will be reduced. If the reflective layer has a long distance from the lateral surface, the light-emitting device has an oversize issue. Thus, improving the light extraction of the light-emitting element and reducing the size of the light-emitting device are important issues.

### SUMMARY

According to one embodiment, a light-emitting device is provided. The light-emitting device includes a light-emitting element, an electrode, a reflective layer and a transparent layer. The light-emitting element includes an upper surface, a first lower surface and a first lateral surface extending between the upper surface and the first lower surface. The electrode is formed below the first lower surface. The reflective layer corresponds to the first lateral surface and includes a first portion and a second portion, wherein the first portion is closer to the electrode than the second portion. There is a first angle included between the first portion and the first lateral surface. There is a second angle included between the second portion and the first lateral surface. The first angle is larger than the second angle. The transparent layer includes an outer portion and an inner portion, wherein the outer portion is formed above the upper surface and the inner portion is formed between the reflective layer and the first lateral surface. The outer portion includes a wavelength conversion material and the inner portion does not include the wavelength conversion material.

According to another embodiment, a light-emitting device is provided. The light-emitting device includes a light-emitting element, an electrode, a reflective layer and a transparent layer. The light-emitting element includes an upper surface, a first lower surface, a first lateral surface extending between the upper surface and the first lower surface, and a thickness from the upper surface to the first lower surface. The electrode is formed below the first lower surface. The reflective layer corresponds to the first lateral surface and includes a first portion and a second portion, wherein the first portion is located below the first lower surface, the second portion directly connects the first portion and is located above the first lower surface, the second portion is separated from the first lateral surface by a minimum distance, the second portion has a slant surface or a curved surface, the minimum distance is larger than half of the thickness. There is a third angle included between the first portion and the second portion, and the third angle is equal to or larger than 135 degrees. The transparent layer includes an outer portion and an inner portion, wherein the outer portion is formed above the upper surface and the inner portion included between the second portion and the first lateral surface. The outer portion includes a wavelength conversion material.

According to another embodiment, a manufacturing method of a light-emitting device is provided. The manufacturing method includes the following steps. an outer portion material is formed on a carrier, wherein the outer portion material includes a wavelength conversion material; an inner portion material is formed on the outer portion material, wherein the inner portion material does not include the wavelength conversion material; a light-emitting element is disposed on the outer portion material, wherein the light-emitting element includes an upper surface, a first lower surface and a first lateral surface extending between the upper surface and the first lower surface, and an electrode is formed below the first lower surface; the inner portion material is singulated to form an inner portion; a reflective layer material corresponding to the first lateral surface is formed, wherein the reflective layer includes a first portion and a second portion. The first portion is closer to the electrode than the second portion. There is a first angle included between the first portion and the first lateral surface. There is a second angle included between the second portion and the first lateral surface. The first angle is larger than the second angle, and the inner portion is formed between the reflective layer and the first lateral surface; and the reflective layer material and the outer portion material are singulated to form a reflective layer and an outer portion, wherein the outer portion and the inner portion constitute a transparent layer.

### BRIEF DESCRIPTION OF THE DRAWINGS

FIG. 1 illustrates a cross sectional view of a light-emitting device according to one embodiment of this invention;

FIG. 2 illustrates a cross sectional view of a light-emitting device according to another embodiment of this invention;

FIG. 3 illustrates a cross sectional view of a light-emitting device according to another embodiment of this invention;

FIG. 4 illustrates a cross sectional view of a light-emitting device according to another embodiment of this invention;

FIGS. 5A to 5F illustrate manufacturing processes of the light-emitting device of FIG. 1;

FIGS. 6A to 6K illustrate manufacturing processes of the light-emitting device of FIG. 2;

FIGS. 7A to 7I illustrate manufacturing processes of the light-emitting device of FIG. 3; and

FIGS. 8A to 8K illustrate manufacturing processes of the light-emitting device of FIG. 4.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The drawings illustrate the embodiments of the application and, together with the description, serve to illustrate the principles of the application. The same name or the same reference number given or appeared in different paragraphs or figures along the specification should has the same or equivalent meanings while it is once defined anywhere of the disclosure. The thickness or the shape of an element in the specification can be expanded or narrowed.

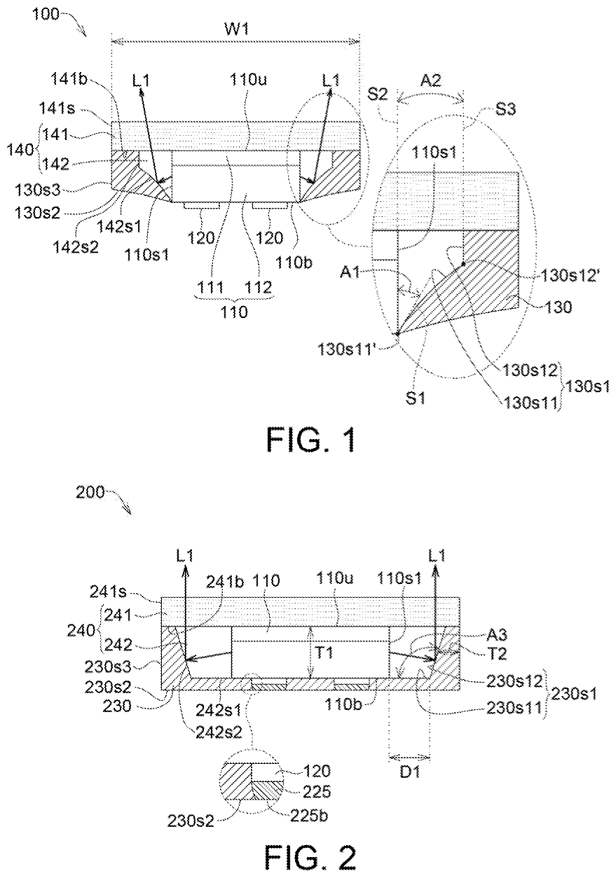

FIG. 1 illustrates a cross sectional view of a light-emitting device 100 according to one embodiment of this invention. The light-emitting device 100 includes a light-emitting element 110, at least one electrode 120, a reflective layer 130 and a transparent layer 140. In one embodiment, the light-emitting device 100 belongs to Chip Scale Package (CSP) level.

The light-emitting element 110 includes an upper surface 110u, a first lower surface 110b and a first lateral surface 110s1 extending between the upper surface 110u and the first lower surface 110b. The electrodes 120 are formed below or on the first lower surface 110b.

In an embodiment, the light-emitting element 110 is, for example, a light-emitting diode. The light-emitting element 110 may include a light-emitting layer 111. In Specific, the light-emitting layer 111 further includes a first type semiconductor layer, a second type semiconductor layer and an active layer. The active layer is formed between the first type semiconductor layer and the second type semiconductor layer. The first type semiconductor layer is realized by such as an n-type semiconductor layer, and the second type semiconductor layer is realized by such as a p-type semiconductor layer. Alternatively, the first type semiconductor layer is realized by such as a p-type semiconductor layer, and the second type semiconductor layer is realized by such as an n-type semiconductor layer. In addition, the active layer may be a single-layered structure or multi-layered structure.

In one embodiment, the light-emitting element 110 further includes a supporting substrate 112. The supporting substrate 112 can hold or support the light-emitting layer 111. Moreover, a surface in the supporting substrate 112 is located away the light-emitting layer 111 and becomes the upper surface 110u of the light-emitting element 110, which is therefore the light extracting surface of the light-emitting element 110. In one embodiment, the supporting substrate 112 is a growth substrate, such as sapphire, for light-emitting layer 111 being epitaxially grown on. In another embodiment, the supporting substrate 112 is not the growth substrate which can be removed or replaced by another substrate (different material, different structure or different shape) during the back-end process of the manufacture of the light-emitting device 100.

The electrode 120 may be realized by a single-layered structure or a multi-layered structure which is made of at least one of materials including gold, aluminum, silver, copper, rhodium (Rh), ruthenium (Ru), palladium (Pd), iridium (Ir), platinum (Pt), chromium, tin, nickel, titanium, tungsten (W), chromium alloys, titanium tungsten alloys, nickel alloys, copper silicon alloy, aluminum silicon copper alloy, aluminum silicon alloy, gold tin alloy, but is not limited thereto. In one embodiment, the electrode 120 includes two electrical contacts which can be electrically connected to the first semiconductor layer and the second semiconductor layer, respectively.

The transparent layer 140 includes an outer portion 141 and an inner portion 142. In one embodiment, the outer portion 141 is formed on or above the upper surface 110u, and the inner portion 142 is formed between the reflective layer 130 and the first lateral surface 110s1.

In one embodiment, the outer portion 141 includes wavelength conversion material, and the inner portion 142 does not include the wavelength conversion material. In an embodiment, the outer portion 141 includes a transparent binder and the wavelength conversion material dispersed in that. The wavelength conversion material may be made of a material including inorganic phosphor, organic fluorescent colorants, semiconductors, or combinations thereof. The semiconductor material includes crystal size in a nano-scale thereof, such as quantum dot luminescent material. In one embodiment, the material of the wavelength converting material is phosphor, and the phosphor can be Y₃Al₆O₁₂:Ce, Gd₃Ga₅O₁₂:Ce, (Lu, Y)₃Al₆O₁₂:Ce, Tb₃Al₆O₁₂:Ce, SrS:Eu, SrGa₂S₄:Eu, (Sr, Ca, Ba)(Al, Ga)₂S₄:Eu, (Ca, Sr)S:(Eu, Mn), (Ca, Sr)S:Ce, (Sr, Ba, Ca)₂Si₅N₅:Eu, (Sr, Ba, Ca)(Al, Ga)Si N₃:Eu, SrLiAl₃N₄:Eu²⁺, CaAlSiON:Eu, (Ba, Sr, Ca)₂SiO₄:Eu, (Ca, Sr, Ba)Si₂O₂N₂:Eu, K₂SiF₆:Mn, K₂TiF₆:Mn, and K₂SnF₆:Mn. The semiconductor material can include II-VI semiconductor compound, III-V semiconductor compound, IV-VI semiconductor compound, or combinations thereof. The quantum dot luminescent material can include a core as emitting light and a shell encapsulating the core. The material of the core can be ZnS, ZnSe, ZnTe, ZnO, CdS, CdSe, CdTe, GaN, GaP, GaSe, GaSb, GaAs, AlN, AlP, AlAs, InP, InAs, Te, PbS, InSb, PbTe, PbSe, SbTe, ZnCdSeS, and CuInS.

The transparent layer 140 may cover the entire of the first lateral surface 110s1, such that the reflective layer 130 is spaced from the first lateral surface 110s1 by the transparent layer 140. As a result, the emitting-light L1 of the light-emitting element 110 can be emitted from the first lateral surface 110s1 to increase light extraction efficiency.

The transparent layer 140 has a first outer surface 142s1 and a second outer surface 142s2. In one embodiment, the first outer surface 142s1 is a curved surface extended between the first lateral surface 110s1 and the second outer surface 142s2, and the second outer surface 142s2 is a plane extended between the first outer surface 142s1 and the outer portion 141 of the transparent layer 140. In the present embodiment, the second outer surface 142s2 is substantially perpendicular to a lower surface 141b of the transparent layer 140. In another embodiment, the first outer surface 142s1 may be a slanted surface. In one embodiment, the outer portion 141 of the transparent layer 140 further has a third lateral surface 141s.

In one embodiment, the reflective layer 130 surrounds the light-emitting element 110 and has an inner surface 130s1 including a first portion 130s11 and a second portion 130s12 connecting with the first portion 130s11, wherein the first portion 130s11 is closer to the electrode 120 than the second portion 130s12. A first angle A1 is an angle between a first direction S1 extended from a first closest point 130s11′ in the first portion 130s11 and a second direction S2 extended from a first closest point 130s11′ in the first lateral surface 110s1. The first closest point 130s11′ is the portion which is closest to the first lower surface 110b in the first portion 130s11.

As illustrated in FIG. 1, a second angle A2 is an angle between a third direction S3 extended from the second closest point 130s12′ in the second portion 130s12 and the second direction S2 extended from the first closest point 130s11′ in the first lateral surface 110s1, wherein the first angle A1 is larger than the second angle A2. The second closest point 130s12′ is the portion which is closest to the first portion 130s11 in the second portion 130s12.

As illustrated in FIG. 1, since the first portion 130s11 is slant with respect to the first lower surface 110b and the first closest point 130s11′ directly contacts the first lateral surface 110s1, a distance between the first portion 130s11 and the first lateral surface 110s1 is zero, and accordingly it can shorten a length W1 of the light-emitting device 100. In addition, the length W1 of the light-emitting device 100 can be flexibly design by adjusting the first angle A1 and the second angle A2.

As illustrated in FIG. 1, the reflective layer 130 has a third outer surface 130s2 and a second lateral surface 130s3, the third outer surface 130s2 is a curved surface extended between the first lower surface 110b and the second lateral surface 130s3, and the second lateral surface 130s3 is a plane and extends between the third outer surface 130s2 and the outer portion 141 of the transparent layer 140. In the present embodiment, the second lateral surface 130s3 is substantially perpendicular to the lower surface 141b of the transparent layer 140. As illustrated in FIG. 1, the second lateral surface 130s3 and the third lateral surface 141s are flush with (or coplanar with) each other due to the second lateral surface 130s3 and the third lateral surface 141s being formed in the same singulation process.

In an embodiment, the reflective layer 130 may be made of a material (first material) including epoxy resin, silicone resin and an another material (second material) with high refractive index dispersed in the first material. The second material may be formed of a plurality of particles. The second material may be Titanium oxide, Zinc oxide, Zirconia, Barium sulfate or Calcium carbonate. The first material may fix the second material in relative positions. In addition, the reflective layer 130 may be a white glue.

FIG. 2 illustrates a cross sectional view of a light-emitting device 200 according to another embodiment of this invention. In the present embodiment, the light-emitting device 200 includes the light-emitting element 110, two electrodes 120, two contacts 225, a reflective layer 230 and a transparent layer 240. In one embodiment, the light-emitting device 200 belongs to CSP level. The functions and materials of the reflective layer 230 and the transparent layer 240 respectively have the same as or similar to the reflective layer 130 and the transparent layer 140 so as to refer to the paragraphs related with FIG. 1.

As illustrated in FIG. 2, each contact 225 is formed below or on the corresponding electrode 120. In the present embodiment, material of the contact 225 is, for example, a solder. The contact 225 has a second lower surface 225b, wherein the second lower surface 225b is a plane, for example.

As illustrated in FIG. 2, each electrode 120 has a lateral surface surrounded by the reflective layer 230, and each contact 225 has a lateral surface surrounded by the reflective layer 230. As a result, the =light extraction can be improved.

The transparent layer 240 includes an outer portion 241 and an inner portion 242. The outer portion 241 is formed above or on the upper surface 110u, and the inner portion 242 included between an inner surface 230s1 of the reflective layer 230 and the first lateral surface 110s1. In addition, in one embodiment, the outer portion 241 includes the wavelength conversion material, and the inner portion 242 does not include the wavelength conversion material.

The transparent layer 240 has a first outer surface 242s1 and a second outer surface 242s2, the first outer surface 242s1 is a plane extending between the first lateral surface 110s1 and the second outer surface 242s2, and the second outer surface 242s2 is a plane extending between the first outer surface 242s1 and the outer portion 241 of the transparent layer 240. In the present embodiment, the first outer surface 242s1 and the first lower surface 110b are flush with (or coplanar with) each other, or the first outer surface 242s1 may be recessed with respect to the first lower surface 110b, or project from the first lower surface 110b.

The transparent layer 240 may cover the entire of the first lateral surface 110s1, such that the reflective layer 230 is spaced from the first lateral surface 110s1 by the transparent layer 240. As a result, the emitting-light L1 of the light-emitting element 110 can be emitted from the first lateral surface 110s1 to increase light extraction efficiency.

The reflective layer 230 surrounds the light-emitting element 110 and has the inner surface 230s1 including a first portion 230s11 and a second portion 230s12. The first portion 230s11 is located below or flush with (or coplanar with) the first lower surface 110b, the second portion 230s12 directly connects the first portion 230s11 and is located above the first portion 230s11. The second portion 230s12 is separated from the first lateral surface 110s1 by a minimum distance D1, the second portion 230s12 has a slant surface or a curved surface, the minimum distance D1 is larger than half of a first thickness T1 of the light-emitting element 110. The larger the first thickness T1 is, the greater the proportion of the side light output to the overall light output is. As a result, the light extraction efficiency of the side light output can be more remarkable by increasing the distance between the first lateral surface 110s1 and the reflecting surface. There is a third angle A3 included between a first portion 230s11 and the second portion 230s12, and the third angle A3 is equal to or larger than 135 degrees. The larger the third angle A3 is, the less the amount of the reflected light is. As a result, the light extraction efficiency of the side light output can be more remarkable by increasing the third angle A3.

In addition, the reflective layer 230 has a second thickness T2. The second thickness T2 is defined as a thickness of the reflective layer 230, corresponding to the position of half of the height in the first thickness T1. In one embodiment, the second thickness T2 is greater than 50 micrometers (μm).

As illustrated in FIG. 2, the reflective layer 230 has a third outer surface 230s2 and a third lateral surface 230s3, the third outer surface 230s2 is a plane extending between one of the electrodes 120 and the third lateral surface 230s3, and extending between the electrodes. Furthermore, the third lateral surface 230s3 is a plane extending between the third outer surface 230s2 and the outer portion 241 of the transparent layer 240. In the present embodiment, the third lateral surface 230s3 is substantially perpendicular to a lower surface 241b of the transparent layer 240. In addition, the outer portion 241 of the transparent layer 240 has a second lateral surface 241s, and the third lateral surface 230s3 and the second lateral surface 241s are flush with (or coplanar with) each other due to the third lateral surface 230s3 and the second lateral surface 241s being formed in the same singulation process. The third outer surface 230s2 and the second lower surface 225b are flush with (or coplanar with) each other due to the third outer surface 230s2 and the second lower surface 225b being formed in the same singulation process.

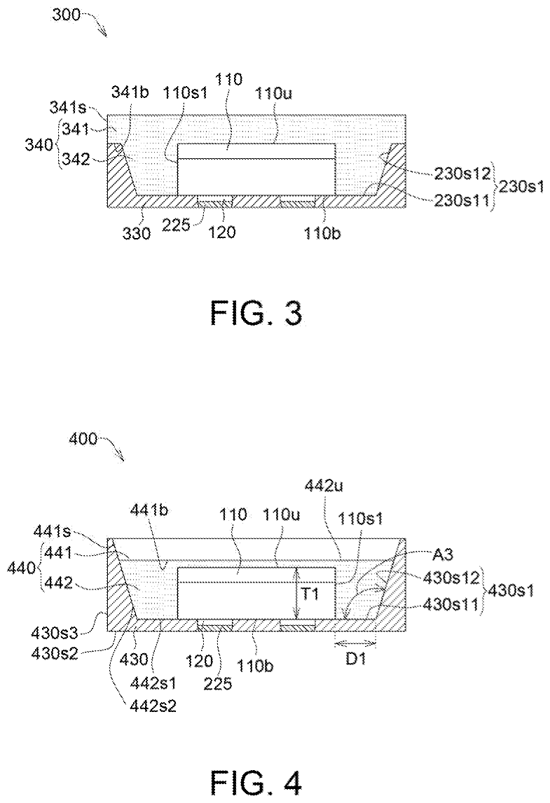

FIG. 3 illustrates a cross sectional view of a light-emitting device 300 according to another embodiment of this invention. In the present embodiment, the light-emitting device 300 includes the light-emitting element 110, two electrodes 120, two contacts 225, the reflective layer 330 and a transparent layer 340. In one embodiment, the light-emitting device 300 belongs to CSP level. The functions and materials of the reflective layer 330 and the transparent layer 340 respectively have the same as or similar to the reflective layer 130 and the transparent layer 140 so as to refer to the paragraphs related with FIG. 1.

The transparent layer 340 includes an outer portion 341 and an inner portion 342. The outer portion 341 is formed above or on the upper surface 110u, and the inner portion 342 is included between the second portion 230s11, the second portion 230s12 and the first lateral surface 110s1. In addition, in one embodiment, the outer portion 341 and the inner portion 342 both include the wavelength conversion material. In the present embodiment, the outer portion 341 and an inner portion 342 are integrated into one piece, and accordingly there is no interfere between the outer portion 341 and the inner portion 342.

FIG. 4 illustrates a cross sectional view of a light-emitting device 400 according to another embodiment of this invention. In the present embodiment, the light-emitting device 400 includes the light-emitting element 110, two electrodes 120, two contacts 225, a reflective layer 430 and a transparent layer 440. In one embodiment, the light-emitting device 400 belongs to CSP level. The functions and materials of the reflective layer 430 and the transparent layer 440 respectively have the same as or similar to the reflective layer 130 and the transparent layer 140 so as to refer to the paragraphs related with FIG. 1.

The transparent layer 440 includes an outer portion 441 and an inner portion 442. The outer portion 441 is formed above the upper surface 110u, and the inner portion 442 included between an inner surface 430s1 of the reflective layer 430 and the first lateral surface 110s1. In addition, in one embodiment, the outer portion 441 includes the wavelength conversion material, and the inner portion 442 does not include the wavelength conversion material.

In the present embodiment, the inner portion 442 includes the wavelength conversion material completely encapsulated by the outer portion 441 and the reflective layer 430, and accordingly the inner portion 442 can be fully protected.

The inner portion 442 has an upper surface 442u, and the outer portion 441 has a lower surface 441b, wherein the upper surface 442u and the lower surface 441b are connected with each other.

The transparent layer 440 has a first outer surface 442s1 and a second outer surface 442s2. In one embodiment, the first outer surface 442s1 is a plane extending between the first lateral surface 110s1 and the second outer surface 442s2, and the second outer surface 442s2 is a slant surface extending between the first outer surface 442s1 and the outer portion 441 of the transparent layer 440. In the present embodiment, the first outer surface 442s1 and the first lower surface 110b are flush with (or coplanar with) each other, or the first outer surface 442s1 may be recessed with respect to the first lower surface 110b, or project from the first lower surface 110b.

The transparent layer 440 may cover the entire of the first lateral surface 110s1, such that the reflective layer 430 is spaced from the first lateral surface 110s1 by the transparent layer 440. As a result, the emitting-light L1 of the light-emitting element 110 can be emitted from the first lateral surface 110s1 to increase light extraction efficiency.

The reflective layer 430 surrounds the light-emitting element 110 and has an inner surface 430s1 including a first portion 430s11 and a second portion 430s12. The first portion 430s1 is located below or flush with (or coplanar with) the first lower surface 110b, the second portion 430s12 directly connects the first portion 430s11 and is located above the first portion 430s1. The second portion 430s12 is separated from the first lateral surface 110s1 by the minimum distance D1, the second portion 430s12 has a slant surface or a curved surface, the minimum distance D1 is larger than half of the first thickness T1 of the light-emitting element 110. There is the third angle A3 included between the first portion 430s11 and the second portion 430s12, and the third angle A3 is equal to or larger than 135 degrees.

As illustrated in FIG. 4, the reflective layer 430 has a third outer surface 430s2 and a third lateral surface 430s3, the third outer surface 430s2 is a plane extending between the electrode 120 and the third lateral surface 430s3, and the third lateral surface 430s3 is a plane defining the entire outer lateral boundary of the light-emitting device 400. The outer portion 441 of the reflective layer 440 has a third lateral surface 441s, and the third lateral surface 441s and the second outer surface 442s2 are flush with (or coplanar with) each other due to the third lateral surface 441s and the second outer surface 442s2 being formed in the same singulation process. In addition, in one embodiment, the second portion 430s12 covers the entire of the second lateral surface 441s and the second outer surface 442s2. In addition, in one embodiment, the third outer surface 430s2 and the second lower surface 225b are flush with (or coplanar with) each other due to the third outer surface 430s2 and the second lower surface 225b being formed in the same singulation process.

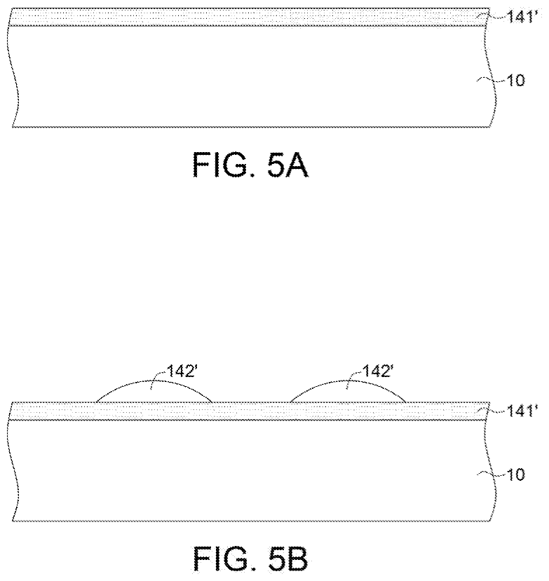

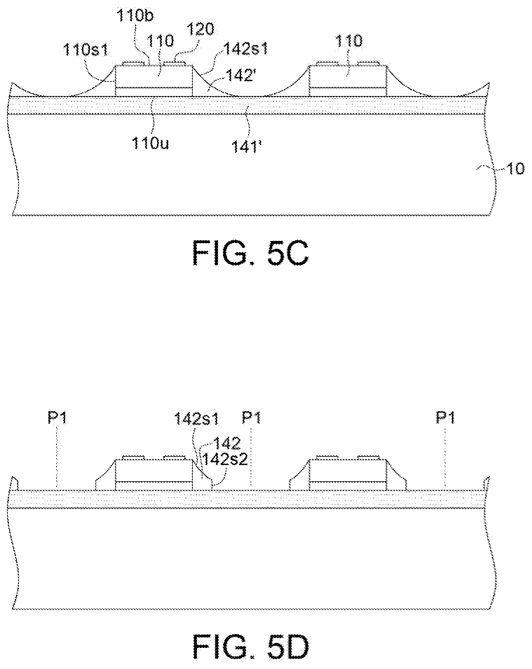

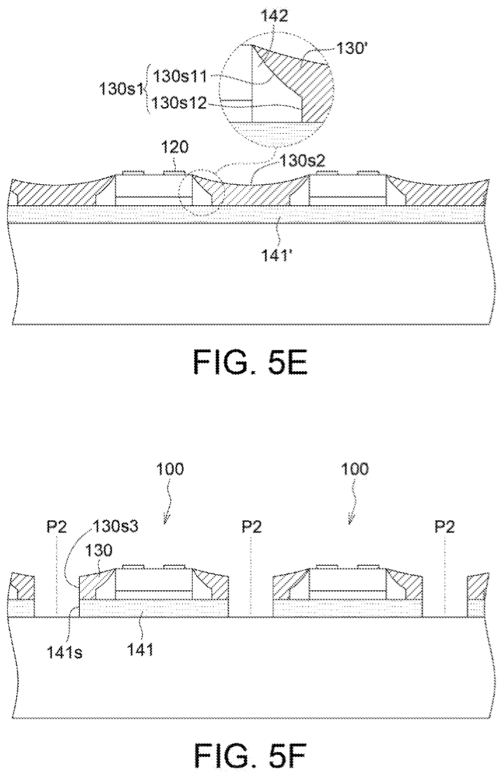

FIGS. 5A to 5F illustrate manufacturing processes of the light-emitting device 100 of FIG. 1.

As illustrated in FIG. 5A, an outer portion material 141′ of the transparent layer 140 is formed on a carrier 10, wherein the outer portion material 141′ includes the wavelength conversion material. The outer portion 141 may be formed by coating, dispensing or molding. For example, a glue (first glue) with the wavelength conversion material may be dispensed on the carrier 10, and then the first glue is cured to form the outer portion material 141′. In one embodiment, the carrier 10 is temporary for the outer portion 141.

As illustrated in FIG. 5B, an inner portion material 142′ of the transparent layer 140 is formed on the outer portion material 141′ by way of, for example, dispensing a glue (second glue) without the wavelength conversion material on the outer portion material 141′. In one embodiment, the inner portion material 142′ and the outer portion material 141′ include the same material expect for the wavelength conversion material. For example, the inner portion material 142′ includes a resin, and the outer portion material 141′ includes the resin and the wavelength conversion material. In addition, the inner portion material 142′ has a condition of fluidity in the present step.

As illustrated in FIG. 5C, at least one light-emitting element 110 is disposed on the outer portion material 141′ where the position of the inner portion material 142′ is formed, wherein the light-emitting element 110 includes the upper surface 110u (faces down in this process), the first lower surface 110b (faces up in this process) and the first lateral surface 110s1 extending between the upper surface 110u and the first lower surface 110b. In addition, at least one electrode 120 is formed on the first lower surface 110b.

In FIG. 5C, the inner portion material 142′ is compressed and then flows laterally to cover the first lateral surface 110s1 of the light-emitting element 110 and forms the first outer surface 142s1. Due to the surface tension of the inner portion material 142′ having fluidity, the first outer surface 142s1 is the curved surface recessed forward the outer portion material 141′.

Then, the inner portion material 142′ may be heated to be solidified or curing after the light-emitting element 110 formed on the outer portion 141.

As illustrated in FIG. 5D, at least one first singulation path P1 passing through the inner portion material 142′ is formed by way of, for example, laser or cutting tool. After the first singulation paths P1 are formed, at least one inner portion 142 having the second outer surface 142s2 is formed.

As illustrated in FIG. 5E, the reflective layer material 130′ surrounding the light-emitting element 110 and the inner portion 142 is formed by way of, for example, dispensing a glue (third glue) on the outer portion material 141′, and then curing the third glue. The reflective layer material 130′ has the inner surface 130s1 and the third outer surface 130s2. In addition, the reflective layer material 130′ has fluidity. Due to the surface tension of the reflective layer material 130′, the third outer surface 130s2 is the curved surface recessed forward the outer portion material 141′. In FIG. 5E, the inner surface 130s1 includes the first portion 130s11 and the second portion 130s12 which cover the entire outer surface of the inner portion 142. The first portion 130s11 is closer to the electrode 120 than the second portion 130s12.

Then, the reflective layer material 130′ may be heated to be solidified or curing.

As illustrated in FIG. 5F, at least one second singulation path P2 passing through the reflective layer material 130′ and the outer portion material 141′ is formed to form at least one light-emitting device 100. The second singulation path P2 may be formed by way of, for example, laser or cutting tool. After the second singulation paths P2 are formed, the second lateral surface 130s3 of the reflective layer 130 and the third lateral surface 141s of the outer portion 141 are formed. Due to the same singulation process, the second lateral surface 130s3 and the third lateral surface 141s are flush with (or coplanar with) each other.

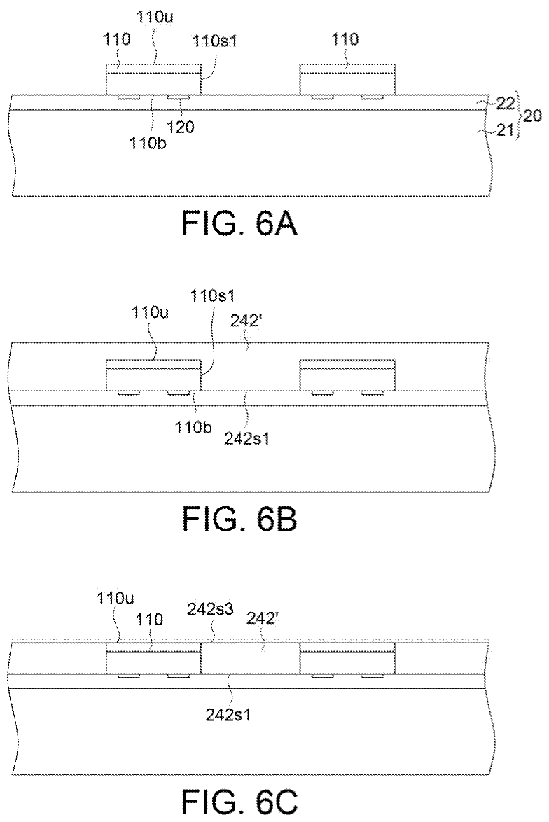

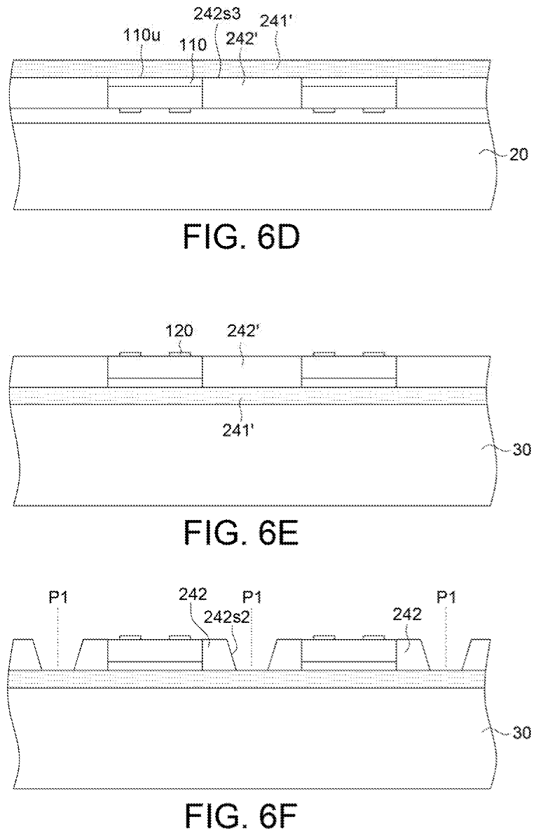

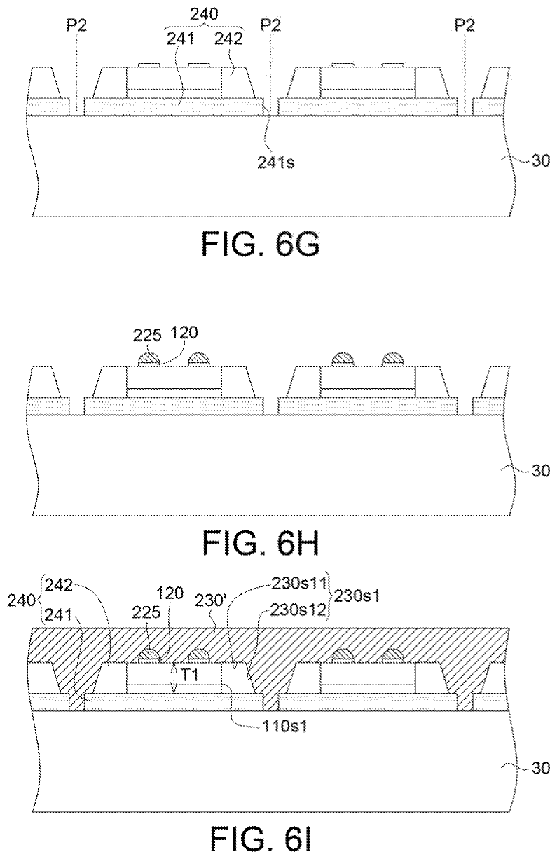

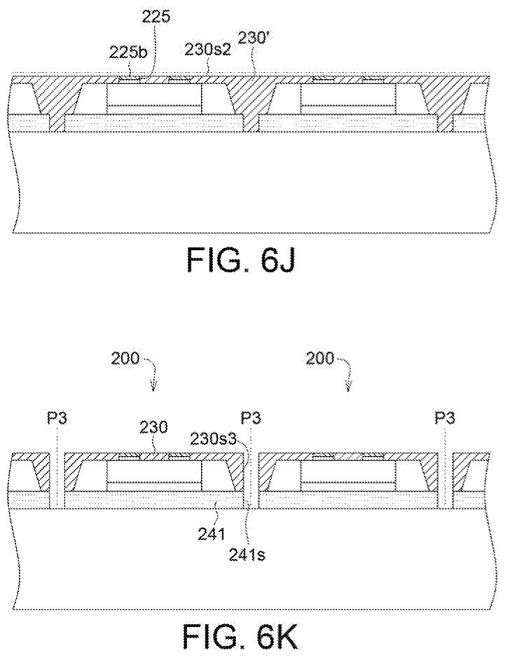

FIGS. 6A to 6K illustrate manufacturing processes of the light-emitting device 200 of FIG. 2.

As illustrated in FIG. 6A, at least one light-emitting element 110 is disposed on the carrier 20. In one embodiment, a plurality of the light-emitting elements 110 is disposed on the carrier 20. The light-emitting element 110 includes the upper surface 110u, the first lower surface 110b and the first lateral surface 110s1 extending between the upper surface 110u and the first lower surface 110b, and at least one electrode 120 is formed below or on the first lower surface 110b. The electrodes 120 are embedded in the carrier 20. In one embodiment, the carrier 20 is temporary for the light-emitting element 110. In detail, the carrier 20 includes a supporting body 21 and an adhesive 22 disposed on the supporting body 21. The light-emitting element 110 may adhered to the adhesive 22, and at least one portion of each electrode 120 is embedded in the adhesive 22. In another embodiment, a portion of the first lateral surface 110s1 may be embedded in the adhesive 22.

As illustrated in FIG. 6B, an inner portion material 242′ surrounding the first lateral surface 110s1 of the light-emitting element 110 and covering the upper surface 110u is formed by coating, molding or dispensing, for example, dispensing. Furthermore, a glue (fourth glue) without the wavelength conversion material may be dispensed on the carrier 20, and then the fourth glue is cured. The inner portion material 242′ has the first outer surface 242s1 adhered to the adhesive 22, wherein the first lower surface 110b and the first outer surface 242s1 are flush with (or coplanar with) each other. In another embodiment, the first outer surface 242s1 may be recessed with respect to the first lower surface 110b, or projected from the first lower surface 110b.

Then, the inner portion material 242′ may be heated to be solidified or curing.

As illustrated in FIG. 6C, a portion of the inner portion material 242′ is removed by way of, for example, grinding or deflashing, to expose the upper surface 110u. After being removed, a surface 242s3 of the inner portion material 242′ opposite to the first outer surface 242s1 is formed, wherein the surface 242s3 and the upper surface 110u are flush with (or coplanar with) each other after grinding.

As illustrated in FIG. 6D, the outer portion material 241′ covering the upper surface 110u and the surface 242s3 is formed by coating, molding or dispensing, for example, dispensing. Furthermore, a glue (fifth glue) with the wavelength conversion material may be dispensed on the light-emitting element 110 and the inner portion material 242′.

As illustrated in FIG. 6E, the light-emitting element 110, the outer portion material 241′ and the inter portion material 242′ are inverted and disposed on a carrier 30 by the outer portion material 241′. Moreover, the carrier 20 is removed from the outer portion material 241′ to expose the electrode 120 of the light-emitting element 110. The outer portion material 241′ is adhered to the carrier 30, and the electrode 120 is exposed and faces upward. In one embodiment, the carrier 30 is a temporary substrate.

As illustrated in FIG. 6F, at least one first singulation path P1 passing through the inner portion material 242′ is formed by way of, for example, laser or cutting tool. After the first singulation paths P1 are formed, at least one the inner portion 242 each having the second outer surface 242s2 is formed.

As illustrated in FIG. 6G, at least one second singulation path P2 passing through the outer portion material 241′ is formed by way of, for example, laser or cutting tool. After the second singulation paths P2 are formed, at least one outer portion 241 having the second lateral surface 241s formed, and one outer portion 241 and one inner portion 242 constitute one transparent layer 240. Due to the outer portion 241 is cut off, the heat stress can be released, and accordingly it can reduce the warpage of the outer portion 241. In another embodiment, the second singulation paths P2 may be omitted if not necessary.

As illustrated in FIG. 6H, at least one contact 225 is formed on the corresponding electrode 120. The contact 225 is, for example, solder bump.

As illustrated in FIG. 6I, a reflective layer material 230′ surrounding the light-emitting element 110 and covering the contact 225, the electrode 120 and the transparent layer 240 is formed by way of, for example, dispensing a glue (sixth glue) on the carrier 30, and then curing the sixth glue. In FIG. 6I, the reflective layer material 230′ has the inner surface 230s1 including the first portion 230s11 and the second portion 230s12 which cover the entire outer surface of the inner portion 242.

Then, the reflective layer material 230′ may be heated to be solidified or curing.

As illustrated in FIG. 6J, a portion of the reflective layer material 230′ and a portion of the contact 225 are removed by way of, for example, grinding or deflashing. After grinding, the lateral surface 225b of the contact 225 and the third outer surface 230s2 of the reflective layer material 230 are formed. Due to the same singulation process, the lateral surface 225b and the third outer surface 230s2 are flush with (or coplanar with) each other after grinding.

As illustrated in FIG. 6K, at least one third singulation path P3 passing through the reflective layer material 230′ and the outer portion 241 is formed by way, for example, laser or tool to form at least one light-emitting device 200. After the third singulation paths P3 are formed, the second lateral surface 241s of the outer portion 241 and the third lateral surface 230s3 of the reflective layer 230 are formed. Due to the same singulation process, the second lateral surface 241s of the third lateral surface 230s3 are flush with (or coplanar with) each other.

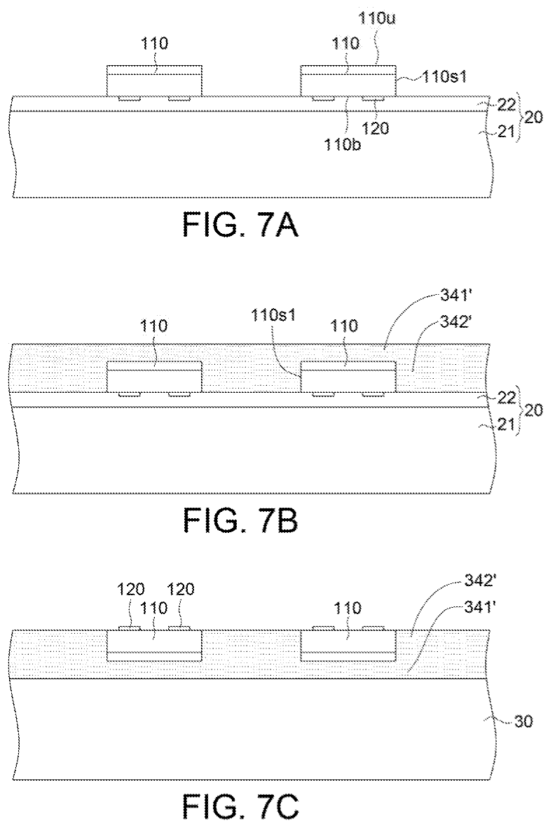

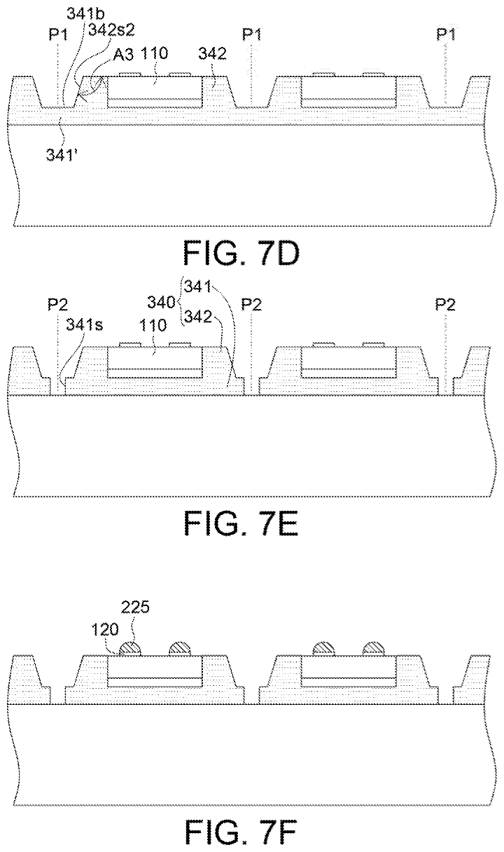

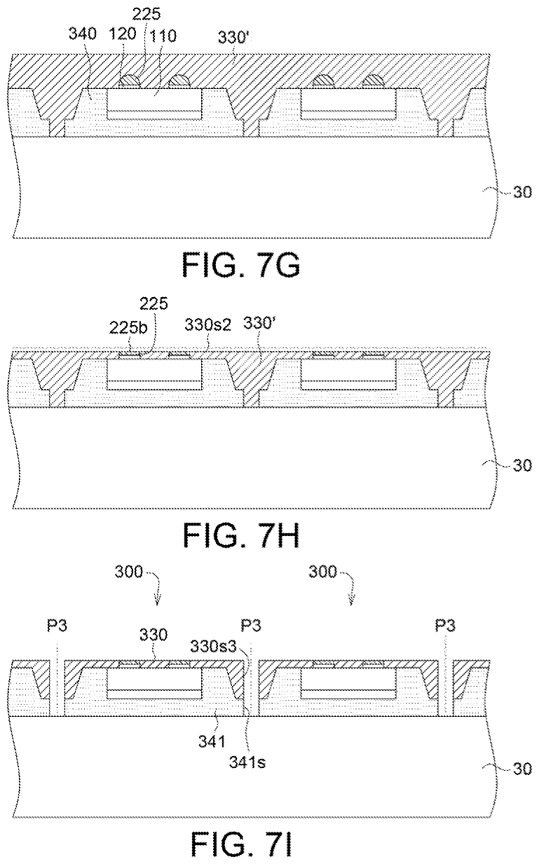

FIGS. 7A to 7I illustrate manufacturing processes of the light-emitting device 300 of FIG. 3.

As illustrated in FIG. 7A, at least one light-emitting element 110 is disposed on the carrier 20. In one embodiment, a plurality of the light-emitting elements 110 is disposed on the carrier 20. The method of arranging the light-emitting element 110 on the carrier 20 can refer to the paragraphs related with FIG. 6A.

As illustrated in FIG. 7B, an outer portion material 341′ and an inner portion material 342′ covering the light-emitting elements 110 and the adhesive 22 are formed by coating, molding or dispensing, for example, dispensing. Furthermore, a glue (seventh glue) with the wavelength conversion material may be dispensed on the carrier 20, and then the seventh glue is cured. The outer portion material 341′ covers the upper surface 110u of the light-emitting element 110, and the inner portion material 342′ surrounds the first lateral surface 110s1 of the light-emitting element 110.

As illustrated in FIG. 7C, the light-emitting element 110, the outer portion material 341′ and the inter portion material 342′ are inverted and then disposed on the carrier 30 by the outer portion material 341′. Moreover, the carrier 20 is removed from the light-emitting element 110 and the inner portion material 342′. The outer portion material 341′ is adhered to the carrier 30, and the electrode 120 is exposed and faces upward.

As illustrated in FIG. 7D, at least one first singulation path P1 passing through the inner portion material 342′ is formed by way of, for example, laser or cutting tool. After the first singulation paths P1 are formed, the second outer surface 342s2 of the inner portion 342 and a lower surface 341b (faces up in this process) of the outer portion material 341′ are formed.

As illustrated in FIG. 7E, at least one second singulation path P2 passing through the outer portion material 341′ is formed by way of, for example, laser or cutting tool. After the second singulation paths P2 are formed, the second lateral surface 341s of the outer portion 341 is formed. Due to the outer portion 341 is cut off, the heat stress can be released, and accordingly it can reduce the warpage of the outer portion 341. In another embodiment, the second singulation paths P2 may be omitted if not necessary.

As illustrated in FIG. 7F, at least one contact 225 is formed on the corresponding electrode 120. The contact 225 is, for example, solderbump.

As illustrated in FIG. 7G, an reflective layer material 330′ surrounding the light-emitting element 110 and covering the contact 225, the electrode 120 and the transparent layer 240. The method of forming the reflective layer material 330′ on the carrier 30 can refer to the paragraphs related with FIG. 6I.

As illustrated in FIG. 7H, a portion of the reflective layer material 330′ and a portion of the contact 225 are removed. The method of removing a portion of the reflective layer material 330′ can refer to the paragraphs related with FIG. 6J.

As illustrated in FIG. 7I, at least one third singulation path P3 passing through the reflective layer material 330′ and the outer portion 341 is formed. The method of cutting the reflective layer material 330′ and the outer portion material 341′ can refer to the paragraphs related with FIG. 6K.

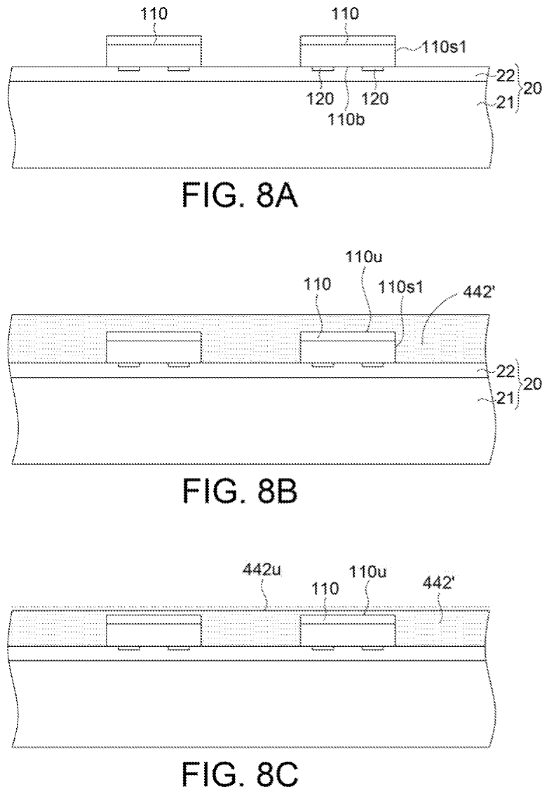

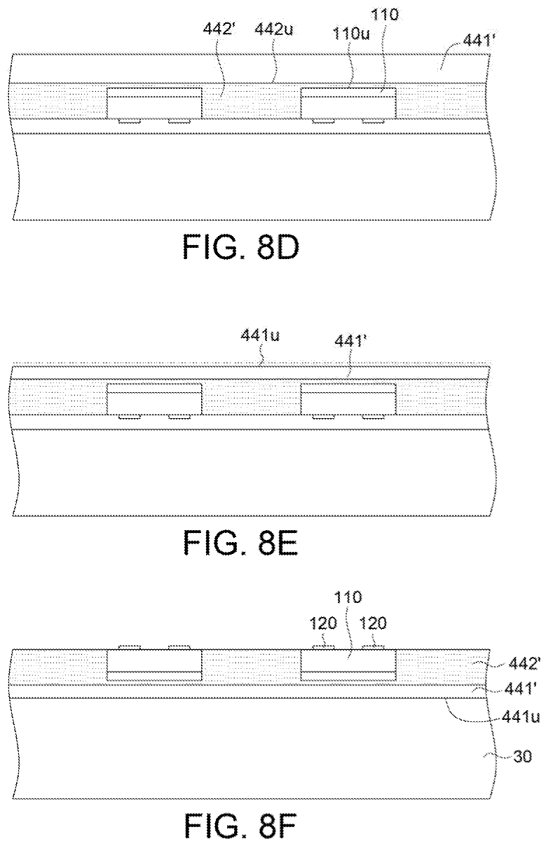

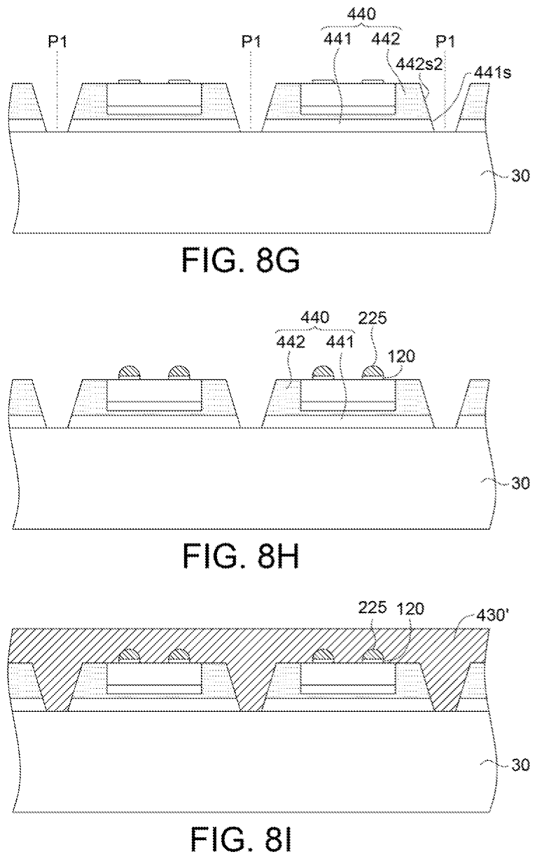

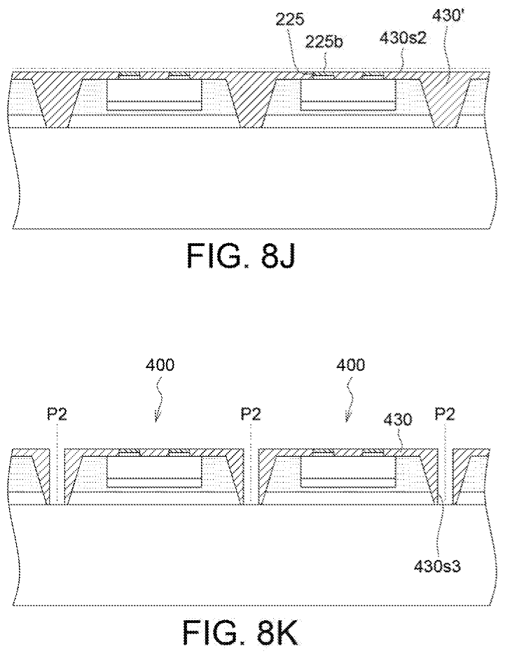

FIGS. 8A to 8K illustrate manufacturing processes of the light-emitting device 400 of FIG. 4.

As illustrated in FIG. 8A, at least one light-emitting element 110 is disposed on the carrier 20. The method of arranging the light-emitting element 110 on the carrier 20 can refer to the paragraphs related with FIG. 6A.

As illustrated in FIG. 8B, the inner portion material 442′ covering the light-emitting elements 110 and the adhesive 22 is formed. The method of forming the inner portion material 442′ on the carrier 20 can refer to the paragraphs related with FIG. 7B.

As illustrated in FIG. 8C, a portion of the inner portion material 442′ is removed by way of, for example, grinding or deflashing. After grinding, another portion of the inner portion material 442′ covering the upper surface 110u forms the upper surface 442u.

As illustrated in FIG. 8D, an outer portion material 441′ covering the upper surface 110u and the upper surface 442u is formed by way of, for example, dispensing a glue (eighth glue) on the light-emitting element 110 and the inner portion material 442′, and then curing the eighth glue.

As illustrated in FIG. 8E, a portion of the outer portion material 441′ is removed by way of, for example, grinding or deflashing. After grinding, an upper surface 441u of the outer portion material 441′ which is a plane is formed.

As illustrated in FIG. 8F, the light-emitting element 110, the outer portion material 441′ and the inter portion material 442′ are inverted and disposed on a carrier 30 by the upper surface 441u (faces down in this process) of the outer portion material 441′. The method of the step in FIG. 8F can refer to the paragraphs related with FIG. 7C.

As illustrated in FIG. 8G, at least one first singulation path P1 passing through the inner portion material 442′ and the outer portion material 441′ is formed by way, for example, laser or cutting tool. After the first singulation paths P1 are formed, at least one the inner portion 442 each having the second outer surface 442s2 and at least one the outer portion 441 each having the second lateral surface 441s are formed, wherein one outer portion 441 and one inner portion 442 constitute one transparent layer 440. Due to the same singulation process, the second lateral surface 441s and the second outer surface 442s2 are flush with (or coplanar with) each other.

As illustrated in FIG. 8H, at least one contact 225 is formed on the corresponding electrode 120. The contact 225 is, for example, solder bump.

As illustrated in FIG. 8I, an reflective layer material 430′ surrounding the light-emitting element 110 and covering the contact 225, the electrode 120 and the transparent layer 440 is formed. The method of forming the reflective layer material 430′ on the carrier 30 can refer to the paragraphs related with FIG. 6A.

As illustrated in FIG. 8J, a portion of the reflective layer material 430′ and a portion of the contact 225 are removed by way of, for example, grinding. The method of removing a portion of the reflective layer material 430′ can refer to the paragraphs related with FIG. 6J.

As illustrated in FIG. 8K, at least one second singulation path P2 passing through the reflective layer material 430′ and the outer portion 341 is formed by way, for example, laser or cutting tool to form at least one light-emitting device 400. After the second singulation paths P2 are formed, at least one the reflective layer 430 each having a third lateral surface 430s3 is formed.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting device, comprises:
a light-emitting element comprising an upper surface, a first lower surface, and a first lateral surface extended between the upper surface and the first lower surface;
an electrode formed below the first lower surface;
a reflective layer, corresponding to the first lateral surface and comprising a first portion and a second portion, wherein the first portion is closer to the electrode than the second portion; and
a transparent layer, comprising an outer portion formed on the upper surface, and an inner portion formed between the reflective layer and the first lateral surface,
wherein the outer portion comprises a wavelength conversion material, and the inner portion is devoid of the wavelength conversion material;
wherein the first portion and the first lateral surface cooperatively define a first angle, the second portion and the first lateral surface cooperatively define a second angle, the first angle is larger than the second angle.

2. The light-emitting device according to claim 1, wherein the reflective layer is totally or partially spaced from the first lateral surface by the transparent layer.

3. The light-emitting device according to claim 1, wherein the transparent layer has a first outer surface and a second outer surface, and the first outer surface is a curved surface extended between the first lateral surface and the second outer surface.

4. The light-emitting device according to claim 1, wherein the transparent layer has a first outer surface and a second outer surface, and the second outer surface is a plane extended between the first outer surface and the outer portion of the transparent layer.

5. The light-emitting device according to claim 3, wherein the reflective layer has a third outer surface and a second lateral surface, and the third outer surface is a curved surface extended between the first lower surface and the second lateral surface.

6. The light-emitting device according to claim 3, wherein the reflective layer has a third outer surface and a second lateral surface, and the second lateral surface is a plane extended between the third outer surface and the outer portion of the transparent layer.

7. The light-emitting device according to claim 1, wherein the reflective layer has a second lateral surface, the outer portion has a third lateral surface, and the second lateral surface and the third lateral surface are flush with each other

8. The light-emitting device according to claim 1, wherein the transparent layer covers the entire of the first lateral surface.

9. The light-emitting device according to claim 1, wherein the reflective layer covers the inner portion.

10. A light-emitting device, comprises:
a light-emitting element comprising an upper surface, a first lower surface, a first lateral surface extended between the upper surface and the first lower surface, and a thickness from the upper surface to the first lower surface;
an electrode formed below the first lower surface;
a reflective layer corresponding to the first lateral surface and comprising a first portion and a second portion, wherein the first portion is located below the first lower surface, the second portion directly connects the first portion and is located above the first lower surface, the second portion is separated from the first lateral surface by a minimum distance, the second portion has a slant surface or a curved surface, the minimum distance is larger than half of the thickness; and
a transparent layer comprising an outer portion formed above the upper surface and an inner portion included between the second portion and the first lateral surface, wherein the outer portion comprises a wavelength conversion material;
wherein the first portion and the second portion cooperatively define a third angle, and the third angle is equal to or larger than 135 degrees.

11. The light-emitting device according to claim 10, wherein the transparent layer has a first outer surface and a second outer surface, and the first outer surface includes a plane extended between the first lateral surface and the second outer surface.

12. The light-emitting device according to claim 10, wherein the transparent layer has a first outer surface and a second outer surface, and the second outer surface includes a plane extended between the first outer surface and the outer portion.

13. The light-emitting device according to claim 10, wherein the reflective layer has a third outer surface and a second lateral surface, and the third outer surface includes a plane between the first lower surface and the second lateral surface.

14. The light-emitting device according to claim 10, wherein the reflective layer has a second lateral surface, the outer portion has a third lateral surface, and the second lateral surface and the third lateral surface are flush with each other.

15. The light-emitting device according to claim 10, further comprises:
a contact formed below the electrode and having a second lower surface;
wherein the reflective layer has a third outer surface, and the third outer surface and the second lower surface are flush with each other.

16. The light-emitting device according to claim 15, wherein the reflective layer surrounds the electrode and the contact.

17. The light-emitting device according to claim 10, wherein the inner portion includes the wavelength conversion material.

18. The light-emitting device according to claim 10, wherein the outer portion has a second lateral surface, the inner portion has a first outer surface, and the first outer surface and the second lateral surface are flush with each other.

19. A manufacturing method of a light-emitting device, comprises:
forming an outer portion material on a carrier, wherein the outer portion material comprises a wavelength conversion material;
forming an inner portion material on the outer portion material, wherein the inner portion material does not comprise the wavelength conversion material;
disposed a light-emitting element on the outer portion material, wherein the light-emitting element comprises an upper surface, a first lower surface and a first lateral surface extending between the upper surface and the first lower surface, and an electrode is formed below the first lower surface;
singulating the inner portion material to form an inner portion;
forming a reflective layer material corresponding to the first lateral surface, wherein the reflective layer has an inner surface comprising a first portion and a second portion, the first portion is closer to the electrode than the second portion, wherein the light-emitting device has a first angle and a second angle, the first angle is included between the first portion and the first lateral surface, the second angle is included between the second portion and the first lateral surface, the first angle is larger than the second angle, and the inner portion is formed between the reflective layer and the first lateral surface; and
singulating the reflective layer material and the outer portion material to form a reflective layer and an outer portion, wherein the outer portion and the inner portion constitute a transparent layer.

20. The manufacturing method according to claim 19, wherein in step of singulating the reflective layer material and the outer portion material to form the reflective layer material and the outer portion, a second lateral surface of the reflective layer and a third lateral surface of the outer portion are formed, and the second lateral surface and the third lateral surface are flush with each other.
